(19) United States
(12) Patent Application Publication
(10) Pub. No.: US 2005/0153188 A1
(43) Pub. Date: Jul. 14, 2005

(54) Component of a fuel cell unit

(75) Inventors: Peter Schenk, Hohenstein (DE); Hans-Rainer Zerfass, Taunusstein (DE)

Correspondence Address: Edward J. Timmer, P.O. Box 770, Richland, MI, 49083, US

(73) Assignee: ElringKlinger AG

(21) Appl. No.: 11/008,059

(22) Filed: Dec. 9, 2004

(30) Foreign Application Priority Data
Dec. 13, 2003 (DE) 103 58 458.7

(51) Int. Cl. H01M 8/10; H01M 2/00; H01M 2/02; H01M 2/08; H01M 2/14; H01L 27/10; H01L 29/73; B23P 19/00; C25D 3/66; C25D 9/00; C25D 11/00; C25D 11/04

(52) U.S. Cl. 429/32; 429/34; 429/35; 429/36; 429/38; 429/39; 205/323; 205/324; 205/233; 29/730

(57) ABSTRACT

In order to provide a component of a fuel cell unit that has an electric insulation effect at the operating temperature of the fuel cell unit and that has an adequate electrically insulating effect and an adequate mechanical strength also at a high operating temperature of the fuel cell unit, it is proposed that the component comprises a basic body and at least one electrically insulating insulation layer, which is disposed on the basic body and contains aluminium oxide, wherein the insulation layer is produced by anodizing an aluminium-containing layer disposed on the basic body.

The present disclosure refers to the subject matter disclosed in German patent application No. 103 58 458.7 of 13 Dec. 2003. The entire description of this earlier application is made a constituent part of the present description by reference (“incorporation by reference”).

### BACKGROUND OF THE INVENTION

The present invention relates to a component of a fuel cell unit that has an electric insulation effect at the operating temperature of the fuel cell unit.

Fuel cell units, for adjustment of the desired operating voltage, are disposed in the required number one on top of the other so as to obtain a fuel cell stack. In order to prevent an electric short circuit, the housings of successive fuel cell units in the fuel cell stack have to be electrically insulated from one another.

In known fuel cell stacks, insulation elements made of glass solder or of ceramic sealing materials are used to achieve the required electric insulation effect.

In the case of some of the sealing materials normally used, the electrical resistance at the operating temperature of a high-temperature fuel cell unit (in the range of approximately 800° C. to approximately 900° C.) is no longer high enough to achieve a satisfactory insulation effect.

The underlying object of the present invention is therefore to provide a component of a fuel cell unit of the initially described type, which component has an adequate electric insulation effect and an adequate mechanical strength also at a high operating temperature of the fuel cell unit.

### SUMMARY OF THE INVENTION

In a component having the features of the preamble of claim 1 this object is achieved according to the invention in that the component comprises a basic body and at least one electrically insulating insulation layer, which is disposed on the basic body and contains aluminium oxide, wherein the insulation layer is produced by anodizing an aluminium-containing layer disposed on the basic body.

In this description and in the accompanying claims, the term “anodizing” is to be understood as the transformation of a metal surface layer into an oxide coating by means of anodic oxidation.

The electrically insulating insulation layer of aluminium oxide produced by anodizing adheres strongly to the basic body and has an adequate electric insulation effect also at the high operating temperature of a high-temperature fuel cell unit.

The material of the electrically insulating insulation layer preferably has an electrical resistivity of at least approximately 2000 Ω*cm (at the operating temperature of the fuel cell, e.g. approximately 800° C.).

It is particularly advantageous when the insulation layer is produced by hard anodising an aluminium-containing layer disposed on the basic body.

In the case of “hard anodizing” or “hard anodic oxidation”, the electrolytic oxidation of aluminium surfaces is produced in extremely supercooled electrolytes and preferably with increased current densities. As electrolytes it is possible to use, in particular, sulphuric acid or a mixture of sulphuric acid and oxalic acid at temperatures of approximately 0° C. to approximately 10° C. Suitable current densities are in the range of approximately 2 A/dm² to approximately 20 A/dm², suitable voltages for the anodic oxidation are in the range of approximately 20 V to approximately 60 V, wherein with increasing thickness of the oxide layer the voltage may be increased.

Suitable hard anodizing techniques are known by the names M.H.C., Alumilite 225/226 or Hardas.

A layer produced by hard anodizing is notable for its high wear-, heat-, corrosion- and electrical resistance.

What is more, extremely wear-resistant oxide layers of up to and beyond 150 μm thick may be produced by hard anodizing.

In order to obtain a proportion of aluminium oxide in the insulation layer that is sufficient for strong adhesion of the insulation layer on the basic body and for an adequate electric insulation effect, it is advantageous when the insulation layer is produced by anodizing a layer that contains aluminium in a fraction of at least approximately 80 percent by weight, preferably of at least approximately 90 percent by weight, in particular of at least approximately 95 percent by weight.

For disposing the aluminium-containing layer on the basic body, any suitable aluminizing method is possible.

In particular, it may be provided that the aluminium-containing layer has been connected to the basic body by plating.

Alternatively or in addition thereto, it may be provided that the aluminium-containing layer has been produced by electrolytic deposition of aluminium on the basic body.

In a preferred development of the invention, it is provided that the basic body comprises a metal alloy.

In order to achieve an adequate corrosion-resistance of the component also at the high operating temperature of an SOFC (solid oxide fuel cell) unit, it is advantageous when the metal alloy is a highly corrosion-resistant steel.

It has moreover proved particularly advantageous when the metal alloy contains iron, chromium, aluminium, silicon, manganese, titanium and/or lanthanum.

In principle, it is sufficient for the basic body of the component to be provided at only one of its surfaces with the insulation layer.

When the basic body is provided at only one of its surfaces with the insulation layer, the basic body at the opposite surface to the insulation layer may be connected by soldering and/or welding to another structural part of a fuel cell unit.

Alternatively, it may however be provided that the basic body is provided at each of two mutually opposite surfaces with an insulation layer.

The component according to the invention is particularly suitable for use in a high-temperature SOFC unit when it has an electric insulation effect at a temperature in the range of approximately 700° C. to approximately 1000° C.

The component may take the form of a separate part of the fuel cell unit that is distinct from the housing parts of the fuel cell unit.

When the component advantageously comprises a ring-shaped region, this component in addition to its electric insulation effect may then be utilized to separate a first gas chamber in the ring interior of the component in a gastight manner from a second gas chamber in the ring exterior of the component.

In particular, in this way a combustion gas channel or waste gas channel, which penetrates the ring interior of the ring-shaped region of the component, may be separated from an oxidant chamber surrounding the ring-shaped region.

Conversely, such a component may also be used to separate an oxidant channel, which is surrounded by the ring-shaped region, in a gastight manner from a combustion gas chamber surrounding the ring-shaped region.

In order, in addition to the electric insulation effect of the component, to be able to exercise a sealing function, the basic body and the insulation layer of the component are preferably of a gastight design.

Claim 13 is directed to a fuel cell stack, comprising a plurality of fuel cell units, which are disposed successively along a stacking direction, and at least one component according to the invention, wherein the component may form an integral part of one of the fuel cell units.

In order to provide a functional unit, which performs both a sealing function and an electrically insulating function in the fuel cell stack, it is preferably provided that a substantially gastight sealing element is disposed between the component having the electric insulation effect and at least one further structural part of a fuel cell unit of the fuel cell stack.

This substantially gastight sealing element may in particular take the form of an annular sealing element.

Such a sealing element may comprise a ceramic sealing material and/or a glass solder.

In particular, it may be provided that the sealing element is formed from a material that does not have an adequate electric insulation effect at the operating temperature of the fuel cell stack, because the electrically insulating function is after all performed by the component according to the invention.

The operational reliability and handling ability of the fuel cell stack are enhanced when the component, in particular the basic body of the component, is fixed to at least one further structural part of a fuel cell unit of the fuel cell stack.

In particular, it may be provided that the component is fixed by soldering and/or welding to the at least one further structural part.

In order during operation of the fuel cell stack to prevent mechanical stresses from arising because of differing degrees of thermal expansion, it is advantageous when the component and the at least one further structural part have coefficients of thermal expansion that differ from one another by at most approximately 50 percent, preferably by at most approximately 20 percent. In said case, as a reference quantity for determining the percentage difference of the coefficients of thermal expansion, in each case the lower coefficient of thermal expansion is to be used.

So that the electrically insulating component at the same time may also perform a sealing function between various gas chambers of the fuel cell stack, it is preferably provided that the component adjoins at least one fluid channel of the fuel cell stack.

In particular, it may be provided that the component encircles the at least one fluid channel.

A further underlying object of the present invention is to provide a method of manufacturing a component of a fuel cell unit that has an electric insulation effect at the operating temperature of the fuel cell unit, which method is usable to manufacture a component that has an adequate electric insulation effect and an adequate mechanical strength also at a high operating temperature.

This object is achieved according to the invention by a method, which comprises the following method steps:
arrangement of an aluminium-containing layer on a basic body;
formation of an electrically insulating insulation layer by anodizing the aluminium-containing layer.

Special developments of the method according to the invention are the subject matter of claims 22 to 32, the advantages of which have already been explained above in connection with special developments of the component according to the invention.

Claims 33 to 40 are directed to a method of manufacturing a fuel cell stack, which comprises a plurality of fuel cell units, whereby at least one component that has an electric insulation effect at the operating temperature of the fuel cell stack is manufactured by the method according to the invention and a plurality of fuel cell units are stacked one on top of the other along a stacking direction.

Further features and advantages of the invention are the subject matter of the following description and the graphic representation of embodiments.

### BRIEF DESCRIPTION OF THE DRAWINGS

FIG. 1 a diagrammatic exploded view of a fuel cell stack, which comprises a plurality of fuel cell units, which are disposed successively along a stacking direction and of which two are illustrated in FIG. 1;

FIG. 2 a diagrammatic section through the fuel cell stack;

FIG. 3 a diagrammatic section through an insulation element and two sealing elements of the fuel cell stack; and

FIG. 4 a diagrammatic section through a second form of construction of an insulation element and a sealing element.

In all of the drawings, identical or functionally equivalent elements are denoted by the same reference characters.

### DETAILED DESCRIPTION OF THE INVENTION

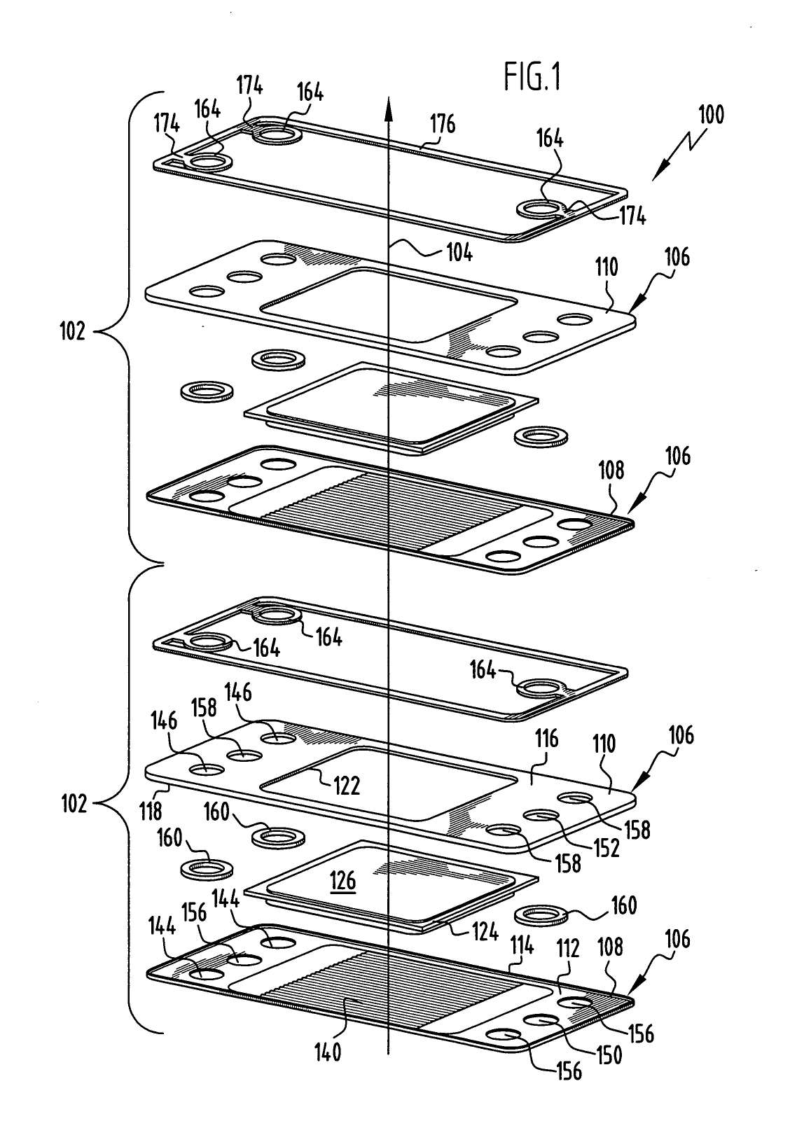

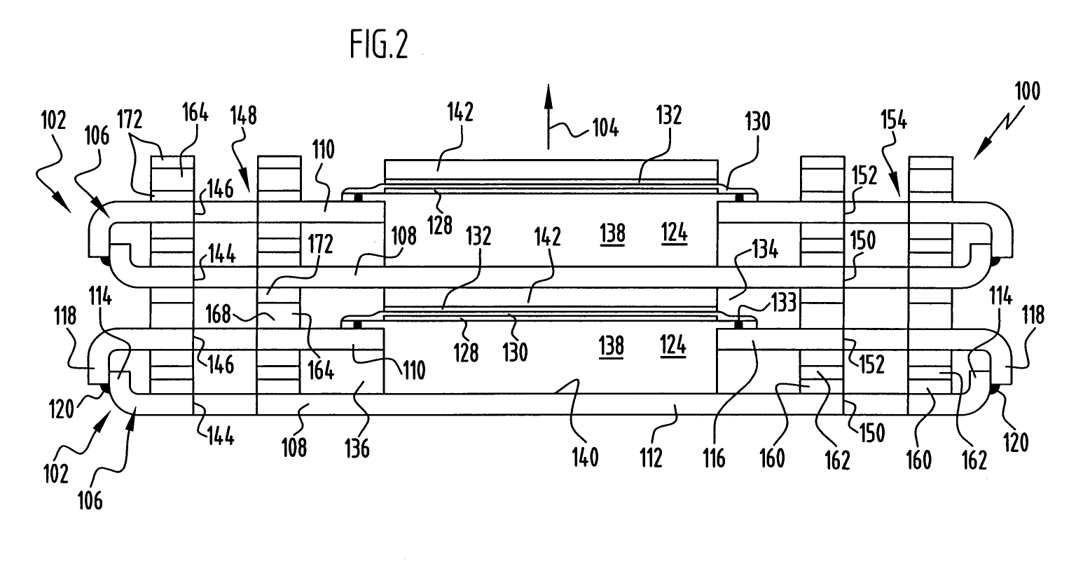

A fuel cell stack, which is illustrated in FIGS. 1 to 3 and denoted as a whole by 100, comprises a plurality of fuel cell units 102 each of an identical design, which are stacked one on top of the other along a vertical stacking direction 104.

Each of the fuel cell units 102 comprises a housing 106, which is composed of a housing lower part 108 and a housing upper part 110.

The housing lower part 108 takes the form of a shaped sheet-metal part and comprises a plate 112, which is aligned substantially at right angles to the stacking direction 104 and at its edges merges into a marginal flange 114, which is bent round substantially parallel to the stacking direction 104.

The housing upper part 110 likewise takes the form of a shaped sheet-metal part and comprises a plate 116, which is aligned substantially at right angles to the stacking direction 104 and at its edges merges into a marginal flange 118, which is bent round substantially parallel to the stacking direction 104 and directed towards the housing lower part 108 and engages over the marginal flange 114 of the housing lower part 108.

The marginal flange 118 of the housing upper part 110 is connected along a circumferential weld seam 120 in a gastight manner to the marginal flange 114 of the housing lower part 108.

The housing upper part 110 and the housing lower part 108 are preferably manufactured from an extremely corrosion-resistant steel, e.g. from the alloy Crofer 22.

The material, Crofer 22, has the following composition: 22 percent by weight chromium, 0.6 percent by weight aluminium, 0.3 percent by weight silicon, 0.45 percent by weight manganese, 0.08 percent by weight titanium, 0.08 percent by weight lanthanum, the remainder being iron.

This material is sold by the company, Thyssen Krupp VDM GmbH, Plettenbergerstr. 2, 58791 Werdohl, Germany.

The housing upper part 110 has a substantially rectangular through-opening 122, which accommodates a substantially cuboidal substrate 124, which carries on its upper side a cathode-electrolyte-anode unit 126.

The cathode-electrolyte-anode unit (CEA unit) 126 comprises an anode 128 disposed directly on the upper side of the substrate 124, an electrolyte 130 disposed on top of the anode 128, and a cathode 132 disposed on top of the electrolyte 130.

The anode 128 is formed from a ceramic material that is electrically conductive at the operating temperature of the fuel cell unit (of approximately 800° C. to approximately 900° C.), being formed for example from ZrO₂ or from an NiZrO₂ cermet (ceramic-metal mixture), which is porous in order to allow a combustion gas, which passes through the substrate 124, to pass through the anode 128 to the electrolyte 130 adjoining the anode 128.

As a combustion gas, it is possible to use e.g. a hydrocarbon-containing gas mixture or pure hydrogen.

The electrolyte 130 preferably takes the form of a solid electrolyte and is formed, for example, from yttrium-stabilized zirconium dioxide.

The cathode 132 is formed from a ceramic material, which is electrically conductive at the operating temperature, for example from (La_{0.8}Sr_{0.2})_{0.98}MnO₃, and is porous in order to allow an oxidant, e.g. air or pure oxygen, from an oxidant chamber 134 adjoining the cathode 132 to pass through to the electrolyte 130.

The gastight electrolyte 130 extends beyond the edge of the gas-permeable anode 128 and beyond the edge of the gas-permeable cathode 132 and lies with its underside directly on the upper side of an edge region of the substrate 124. The edge region of the substrate 124 is welded in a gastight manner to the housing upper part 110, wherein by virtue of the welding operation a gastight zone 133 is formed in the edge region of the substrate 124 and extends through the entire height of the edge region of the substrate 124. This gastight zone 133 is covered by the electrolyte 130 so that the combustion gas chamber 136 of the fuel cell unit 102 formed by the inner region of the substrate 124 and the gap between the housing lower part 108 and the housing upper part 110 is separated in a gastight manner from the oxidant chamber 134 situated above the electrolyte 130.

The substrate 124 may, for example, take the form of a metallic knitted fabric, a metallic woven fabric, a metallic braided fabric, a metallic non-woven fabric and/or a porous body made of sintered or compacted metal particles.

As the substrate 124 is in electrically conducting contact with the anode 128, the substrate 124 is also referred to as anode contact body 138.

At its underside remote from the anode, the anode contact body 138 is soldered to a contact bank 140, which is disposed centrally on the housing lower part 108.

The contact bank 140 may be designed, for example, in the shape of a corrugated sheet.

The cathode 132 is connected in an electrically conducting manner to a cathode contact body 142 (not shown in the exploded view of FIG. 1), which is disposed above the CEA unit 126 and of which the upper side remote from the cathode 132 is soldered to the underside of the housing lower part 108 of a further fuel cell unit 102 situated above it in the stacking direction 104.

The cathode 132 of each fuel cell unit 102 is therefore connected by the cathode contact body 142, the housing lower part 108 of the adjacent fuel cell unit 102 and the anode contact body 138 of the adjacent fuel cell unit 102 in an electrically conducting manner to the anode 128 of the fuel cell unit 102 situated above it in the stacking direction 104.

During operation of the fuel cell stack 100, the CEA unit 126 of each fuel cell unit 102 has a temperature of e.g. approximately 850° C., at which the electrolyte 130 is conductive for oxygen ions. The oxidant from the oxidant chamber 134 acquires electrons at the cathode 132 and transfers bivalent oxygen ions to the electrolyte 130, which migrate through the electrolyte 130 to the anode 128. At the anode 128, the combustion gas from the combustion gas chamber 136 is oxidized by the oxygen ions from the electrolyte 130 and in the process transfers electrons to the anode 128.

The electrons liberated during the reaction at the anode 128 are supplied from the anode 128 via the anode contact body 138, the housing lower part 108 and the cathode contact body 142 to the cathode 132 of an adjacent fuel cell unit 100 and hence enable the cathode reaction.

In order to be able to supply combustion gas to the combustion gas chambers 136 of the fuel cell units 102, the housing lower parts 108 are provided with combustion-gas through-openings 144 and the housing upper parts 110 with combustion-gas through-openings 146, which are mutually aligned, so that vertical combustion gas channels 148 penetrating the combustion-gas through-openings 144, 146 are formed.

In order to be able to remove waste gas from the fuel cell stack 100, the housing lower parts 108 are provided with waste-gas through-openings 150 and the housing upper parts 110 with waste-gas through-openings 152, which are mutually aligned, so that one or more vertical waste gas channels 154 penetrating the waste-gas through-openings 150, 152 are formed.

In order to be able to supply oxidant to the oxidant chambers 134 of the fuel cell units 102 and remove excess oxidant from the fuel cell stack 100, the housing lower parts 108 are provided with oxidant through-openings 156 and the housing upper parts 110 with oxidant through-openings 158, which are mutually aligned, so that vertical oxidant channels penetrating the oxidant through-openings 156, 158 are formed.

In order to increase the mechanical stability of the housings 106 of the fuel cell units 102, there may be disposed between the housing lower part 108 and the housing upper part 110 of each fuel cell unit 102 spacer elements 160, which in each case encircle the combustion gas channels 148 and/or the waste gas channels 154 and which have radial through-channels 162 to allow combustion gas to pass out of the combustion gas channels 148 into the combustion gas chambers 136 and allow waste gas to pass out of the combustion gas chambers 136 into the waste gas channels 154 respectively. These spacer elements 160 may be formed, for example, from metallic or ceramic material and need not have an electric insulation effect.

However, in order to prevent an electric short circuit, the housings 106 of fuel cell units 102 disposed successively along the stacking direction 104 have to be electrically insulated from one another. In order to achieve this electric insulation effect, between the upper side of the housing upper part 110 of each fuel cell unit 102 and the underside of the housing lower part 108 of the fuel cell unit 102 situated above there are disposed components, which have an electric insulation effect at the operating temperature of the fuel cell stack 100 and are referred to hereinafter as insulation elements 164.

Each of the insulation elements 164 is of a substantially annular design, with the ring axis aligned parallel to the stacking direction 104, and encircles in each case one of the combustion gas channels 148 or one of the waste gas channels 154.

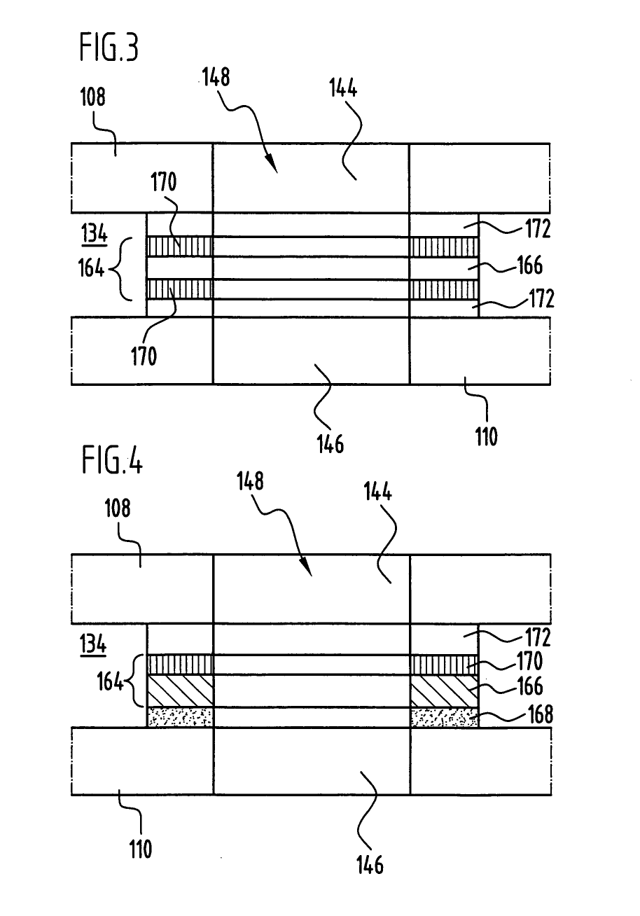

One of these annular insulation elements 164 is shown in greater detail in FIG. 3.

As may be seen from FIG. 3, the insulation element 164 comprises an annular basic body 166 made of a metal material.

In particular, the basic body 166 may be formed from a highly corrosion-resistant steel, e.g. from the alloy Crofer 22, the composition of which has already been indicated above.

Disposed on each of the two mutually opposite end faces of the annular basic body 166 is an insulation layer 170, which is electrically insulating at the operating temperature of the fuel cell stack 100 and which has been produced by anodizing an aluminium-containing layer adhering to the basic body 166 and hence contains electrically non-conducting aluminium oxide.

As the insulation element 164 surrounds a combustion gas channel 148 and the combustion gas channel 148 has to be separated in a gastight manner from the oxidant chamber 134 surrounding the insulation element 164, there is disposed between the insulation layers 170 of the insulation element 164 and the underside of the adjacent housing lower part 108 and/or the upper side of the adjacent housing upper part 110 in each case an annular sealing element 172, which is formed from a gastight material, e.g. from a ceramic sealing compound.

Examples of ceramic sealing compounds suitable for this purpose are known in particular from DE 102 06 863 A1.

One example of such a suitable sealing compound known from DE 102 06 863 A1 is manufactured by adding 20 parts by weight of kaolin and 12 parts by weight of boron nitride (α-BN, hexagonal graphite-analogous BN, mean particle size 4 μm) to 68 parts by weight of water glass.

A further example of a suitable sealing compound known from DE 102 06 863 A1 is obtained by adding boron nitride (specifications as above) to a commercially obtainable water-glass-based lime adhesive, namely Canol 460 of the company Segliwa GmbH, Wiesbaden, Germany, so that the mixture contains 17 percent boron nitride.

By means of the sealing element 172 made of the ceramic sealing compound the insulation element 164 is connected adhesively to the adjacent housing lower part 108, wherein at the same time the gas channel surrounded by the insulation element 164 is separated in a gastight manner from the exterior of the insulation element 164.

To allow the insulation elements 164, which are disposed in each case between the housings 106 of two fuel cell units 102, to be handled easily as a unit, it may be provided that these annular insulation elements 164 are connected in each case by a web 174 to a substantially rectangular frame 176, wherein the frame 176 and the webs 174, like the annular insulation elements 164 themselves, are formed from a basic body made of a metal material and aluminium oxide layers produced on the surfaces of the basic body (see FIG. 1).

The procedure for manufacturing and assembling the previously described insulation elements 164 is as follows:
First, insulation element blanks of the desired shape, in particular in the shape of a ring, are removed, in particular cut or punched, from a sheet of the metal material (e.g. Crofer 22) selected for the basic body 166, which sheet is aluminium-plated on both sides and is of the desired thickness (e.g. in the range of approximately 200 μm to approximately 400 μm).

These insulation element blanks are then subjected to electrolytic hard anodizing, in the course of which the aluminium plated onto the basic body 166 is thoroughly oxidized, thereby producing at each end face of the basic body 166 an electrically insulating insulation layer 170 of aluminium oxide.

After production of the insulation layers 170 on the basic bodies 166, the ceramic sealing compound is applied onto the exposed upper side of the insulation layers 170 remote from the basic body 166 and/or onto the underside of the respective associated housing lower parts 108 and/or onto the upper side of the respective associated housing upper parts 110.

The housings 106 of the fuel cell units 102 of the fuel cell stack 100 are then stacked one on top of the other, with the insulation elements 164 disposed in each case therebetween, and the fuel cell stack 100 is dried at a temperature of e.g. approximately 70°° C. to approximately 80° C.

Hardening of the sealing elements 172 made of the ceramic sealing compound is effected the first time the fuel cell stack 100 is heated up to its operating temperature.

The welding of the housing upper parts 110 to the respective housing lower parts 108 along the weld seams 120 may be carried out before or after the adhesion of the insulation elements 164 onto the housing upper parts 110 and/or the housing lower parts 108.

Instead of removing the insulation element blanks from a sheet of an aluminium-plated metal material, the procedure may be such that the basic bodies 166 of the insulation elements 164 are removed, in particular cut or punched, in the desired shape, in particular in the shape of a ring, from a sheet of the desired metal material of the desired thickness (e.g. in the range of approximately 200 μm to approximately 400 μm), and then on each end face of the basic bodies 166 an aluminium layer is produced by electrolytic deposition of aluminium in aprotic solution.

After producing the aluminium layers on the basic bodies 166, the insulation layers 170 are then produced in the manner described above by hard anodizing the aluminium layers, and assembly of the insulation elements 164 thus manufactured is effected in the manner described above.

Instead of Crofer 22, the basic bodies 166 of the insulation elements 164 may be formed in particular from the steel alloy having the material number 1.4310.

A second form of construction of an insulation element 164, which is illustrated in FIG. 4, differs from the previously described form of construction in that the annular basic body 166 is provided only at one of its end faces, namely at the upper side facing the housing lower part 108, with an insulation layer 170 of aluminium oxide.

The opposite end face of the annular basic body 166 to the insulation layer 170 is connected by a solder layer 168 to the upper side of the housing upper part 110.

Even though in this form of construction there is only a single insulation layer 170 of aluminium oxide, this one layer is in fact sufficient to achieve an adequate electric insulation effect at the operating temperature of the fuel cell stack 100.

The electrically insulating insulation layer 170 of the insulation element 164 is connected by an annular sealing element 172, which may be formed from one of the ceramic sealing compounds described above in connection with the first form of construction and encircles one of the gas channels of the fuel cell stack 100, in a gastight manner to the underside of the housing lower part 108 of the fuel cell unit 102 situated above.

The procedure for manufacturing and assembling the second form of construction of the insulation element 164 is as follows:
First, insulation element blanks are removed, in particular cut or punched, in the desired shape, in particular in the shape of a ring, from a sheet of the metal alloy selected for the basic body 166, which sheet is aluminium-plated on one side and is of the desired thickness (e.g. in the region of approximately 200 μm to approximately 400 μm).

Then, by hard anodizing the insulation element blanks the aluminium layer is thoroughly oxidized, thereby forming the insulation layer 170 of aluminium oxide.

After production of the insulation layers 170 on the basic bodies 166, each basic body 166 is soldered onto the upper side of the respective associated housing upper part 110.

The ceramic sealing mass is then applied onto the exposed upper side of the insulation layers 170 and/or onto the underside of the respective associated housing lower parts 108.

The housings 106 of the fuel cell units 102 of the fuel cell stack 100 are then stacked one on top of the other, with the insulation elements 164 disposed in each case therebetween, and the fuel cell stack 100 is dried at a temperature of e.g. approximately 70° C. to approximately 80° C.

Hardening of the sealing elements 172 made of the ceramic sealing compound is effected the first time the fuel cell stack 100 is heated up to its operating temperature.

In this case too, the welding of the housing upper parts 110 to the respective housing lower parts 108 along the weld seams 120 may be effected before or after the soldering of the basic bodies 166 onto the housing upper parts 110.

As an alternative to the use of insulation element blanks of metal material that is aluminium-plated on one side, it may be provided that the basic bodies 166 are removed, in particular cut or punched, in the desired shape, in particular in the shape of a ring, from a sheet of the desired metal material of the desired thickness (e.g. in the region of approximately 200 μm to approximately 400 μm) and then an aluminium layer is produced on one side of the respective basic body 166 by electrolytic deposition of aluminium in aprotic solution, wherein the opposite side of the respective basic body 166 is masked to prevent a deposition of aluminium on both sides.

The electrically insulating insulation layer 170 of aluminium oxide is then formed from the deposited aluminium layer by hard anodizing.

The insulation element 164 thus produced is soldered in the manner already described above onto the upper side of the respective associated housing upper part 110, and the further assembly steps are carried out in the manner described above.

1. Component of a fuel cell unit that has an electric insulation effect at the operating temperature of the fuel cell unit, wherein the component comprises a basic body and at least one electrically insulating insulation layer, which is disposed on the basic body and contains aluminium oxide, wherein the insulation layer is produced by anodizing an aluminium-containing layer disposed on the basic body.

2. Component according to claim 1, wherein the insulation layer is produced by hard anodizing an aluminium-containing layer disposed on the basic body.

3. Component according to claim 1, wherein the insulation layer is produced by anodizing a layer, which contains aluminium in a proportion of at least approximately 80 percent by weight, preferably of at least 90 percent by weight, in particular of at least approximately 95 percent by weight.

4. Component according to claim 1, wherein the aluminium-containing layer has been connected to the basic body by plating.

5. Component according to claim 1, wherein the aluminium-containing layer has been produced by electrolytic deposition of aluminium on the basic body.

6. Component according to claim 1, wherein the basic body comprises a metal alloy.

7. Component according to claim 6, wherein the metal alloy is a highly corrosion-resistant steel.

8. Component according to claim 6, wherein the metal alloy contains iron, chromium, aluminium, silicon, manganese, titanium and/or lanthanum.

9. Component according to claim 1, wherein the basic body is provided at only one of its surfaces with an insulation layer.

10. Component according to claim 1, wherein the basic body is provided at each of two mutually opposite surfaces with an insulation layer.

11. Component according to claim 1, wherein the component has an electric insulation effect at a temperature in the range of approximately 700° C. to approximately 1000° C.

12. Component according to claim 1, wherein the component comprises an annular region.

13. Fuel cell stack, comprising a plurality of fuel cell units, which are disposed successively along a stacking direction, and at least one component according to claim 1.

14. Fuel cell stack according to claim 13, wherein a substantially gastight sealing element is disposed between the component and at least one further structural part of a fuel cell unit of the fuel cell stack.

15. Fuel cell stack according to claim 14, wherein the sealing element comprises a ceramic sealing material and/or a glass solder.

16. Fuel cell stack according to claim 13, wherein the component is fixed to at least one further structural part of a fuel cell unit of the fuel cell stack.

17. Fuel cell stack according to claim 16, wherein the component is fixed by soldering and/or welding to the at least one further structural part.

18. Fuel cell stack according to claim 16, wherein the component and the at least one further structural part have coefficients of thermal expansion that differ from one another by at most approximately 50 percent, preferably by at most approximately 20 percent.

19. Fuel cell stack according to claim 13, wherein the component adjoins at least one fluid channel of the fuel cell stack.

20. Fuel cell stack according to claim 19, wherein the component encircles the at least one fluid channel.

21. Method of manufacturing a component of a fuel cell unit that has an electric insulation effect at the operating temperature of the fuel cell unit, comprising the following method steps:
arrangement of an aluminium-containing layer on a basic body;
formation of an electrically insulating insulation layer by anodizing the aluminium-containing layer.

22. Method according to claim 21, wherein the insulation layer is produced by hard anodizing the aluminium-containing layer disposed on the basic body.

23. Method according to claim 21, wherein the insulation layer is produced by anodizing a layer, which contains aluminium in a proportion of at least approximately 80 percent by weight, preferably of at least approximately 90 percent by weight, in particular of at least approximately 95 percent by weight.

24. Method according to claim 21, wherein the aluminium-containing layer is disposed on the basic body by plating.

25. Method according to claim 21, wherein the aluminium-containing layer is produced by electrolytic deposition of aluminium on the basic body.

26. Method according to claim 21, wherein the basic body comprises a metal alloy.

27. Method according to claim 26, wherein the metal alloy is a highly corrosion-resistant steel.

28. Method according to claim 26, wherein the metal alloy contains iron, chromium, aluminium, silicon, manganese, titanium and/or lanthanum.

29. Method according to claim 21, wherein only one surface of the basic body is provided with an aluminium-containing layer.

30. Method according to claim 21, wherein two mutually opposite surfaces of the basic body are each provided with an aluminium-containing layer.

31. Method according to claim 21, wherein an insulation layer is produced, which has an electric insulation effect at a temperature in the range of approximately 700° C. to approximately 1000° C.

32. Method according to claim 21, wherein a basic body is used, which comprises an annular region.

33. Method of manufacturing a fuel cell stack, which comprises a plurality of fuel cell units, whereby at least one component that has an electric insulation effect at the operating temperature of the fuel cell stack is manufactured by a method according to claim 21 and a plurality of fuel cell units are stacked one on top of the other along a stacking direction.

34. Method according to claim 33, wherein a substantially gastight sealing element is disposed between the component and at least one further structural part of a fuel cell unit of the fuel cell stack.

35. Method according to claim 34, wherein the sealing element is formed from a ceramic sealing material and/or from a glass solder.

36. Method according to claim 33, wherein the component is fixed to at least one further structural part of a fuel cell unit of the fuel call stack.

37. Method according to claim 36, wherein the component is fixed by soldering and/or welding to the at least one further structural part.

38. Method according to claim 36, wherein the component and the at least one further structural part have coefficients of thermal expansion that differ from one another by at most approximately 50 percent, preferably by at most approximately 20 percent.

39. Method according to claim 33, wherein the component is disposed in such a way that it adjoins at least one fluid channel of the fuel cell stack.

40. Method according to claim 39, wherein the component is disposed in such a way that it encircles the at least one fluid channel.
